(19) United States
(12) Patent Application Publication
(10) Pub. No.: US 2008/0127487 A1
(43) Pub. Date: Jun. 5, 2008

(54) METHOD FOR PLACING A COMPONENT ON A SUBSTRATE, AS WELL AS SUCH A DEVICE

(75) Inventor: Hubert Francijn Maria Hoogers, Wintelre (NL)

Correspondence Address: FOLEY AND LARDNER LLP;SUITE 500, 3000 K STREET NW, WASHINGTON, DC, 20007, US

(73) Assignee: Assembleon N.V.

(21) Appl. No.: 11/934,384

(22) Filed: Nov. 2, 2007

(30) Foreign Application Priority Data
Nov. 3, 2006 (NL) 1032810

(51) Int. Cl. H01L 21/67; H01R 43/00

(52) U.S. Cl. 29/834; 29/739; 29/832; 29/833

(57) ABSTRACT

According to a method and in a device for placing a component on a substrate, a component is moved in a supply direction until it abuts against a stop. The component is then moved at least in a vertically extending pick-up direction and subsequently positioned on the substrate. The component is pivoted near said stop, about a pivot axis that extends transversely to the supply direction and the pick-up direction.

The invention relates to a method for placing a component on a substrate, which component is moved in a supply direction until it abuts against a stop, after which the component is moved at least in a vertically extending pick-up direction and subsequently positioned on the substrate.

The invention also relates to a device suitable for placing a component on a substrate, which device is provided with a guide comprising a stop for moving the component in a supply direction, as well as with a pickup element for moving the component in an at least vertically extending pickup direction.

With such a method and device, which are known from European patent application EP-A2-0 853 448, components contained in a so-called bulk cassette are transported via a guide until they abut against a stop. Near said stop, a component is moved in vertical direction away from the stop, and subsequently it is moved in horizontal and vertical direction to a desired placement position on a substrate and positioned on said substrate. Such a component usually has a length L, a width B and a height H, wherein L>B>H. The component is usually placed on the substrate in such a manner that the longitudinal direction and the transverse direction of the component extend parallel to those of the substrate.

Lately components are frequently being placed on a substrate or in an opening in a substrate with their longitudinal direction extending transversely to the substrate. Supplying and placing components on a substrate in this manner is not possible with the known method and device.

The object of the invention is to provide a method by means of which components can be placed on the substrate in a desired orientation.

This object is accomplished with the method according to the invention in that the component is pivoted near said stop, about a pivot axis that extends transversely to the supply direction and the pick-up direction.

By pivoting the component about the pivot axis, the component is placed in the orientation in which it is subsequently positioned on the substrate. It is noted that the phrase “on the substrate” as used herein is understood to include positioning a component in an opening formed in the substrate.

It is noted that from JP-2000004099 there is known a device for orienting components so that all components will be aligned with the same edge on the same side. To that end, components are guided into a recess, where the orientation of the component is established. Depending on said orientation, the component is rotated either clockwise and discharged via an opening 5c or anticlockwise and discharged through the opening 5d via an opening 5b and the channel 8. The components thus oriented are then returned to a horizontal position and subsequently guided into a component tube.

It is not known from said document to pivot components at the location of a stop and subsequently pick up the components in said pivoted position and place them on a substrate.

One embodiment of the method according to the invention is characterised in that the component is moved with its longitudinal direction in the supply direction, after which it is pivoted about the pivot axis and subsequently moved with its longitudinal direction in the pickup direction.

When the component is being moved in the supply direction, the component will usually align itself in the supply direction in such a manner that the longitudinal direction of the component extends parallel to the supply direction. When the component is subsequently pivoted about a pivot axis extending transversely to the supply direction and the pickup direction, the longitudinal direction of the component will extend parallel to the pickup direction. Following that the component can be positioned on the substrate in this orientation in a simple manner.

Another embodiment of the method according to the invention is characterised in that the supply direction extends transversely to the pickup direction.

The supply direction preferably extends horizontally in that case, whereas the pickup direction preferably extends vertically. In this way components can be supplied and picked up in a simple manner.

The invention also relates to a device which is characterised in that the device further comprises means located near said stop for pivoting the component about a pivot axis extending transversely to the supply direction and the pickup direction.

When such means are used, the orientation of the component is changed in a simple manner.

Another embodiment of the device according to the invention is characterised in that said means comprise a cylindrical element which is pivotable about said pivot axis, which element is provided with a chamber which extends transversely to the pivot axis and which is provided with said stop on a side remote from the guide.

A component can be pivoted about the pivot axis in a comparatively simple manner when such a cylindrical element is used.

The invention will now be explained in more detail with reference to the drawings, in which:

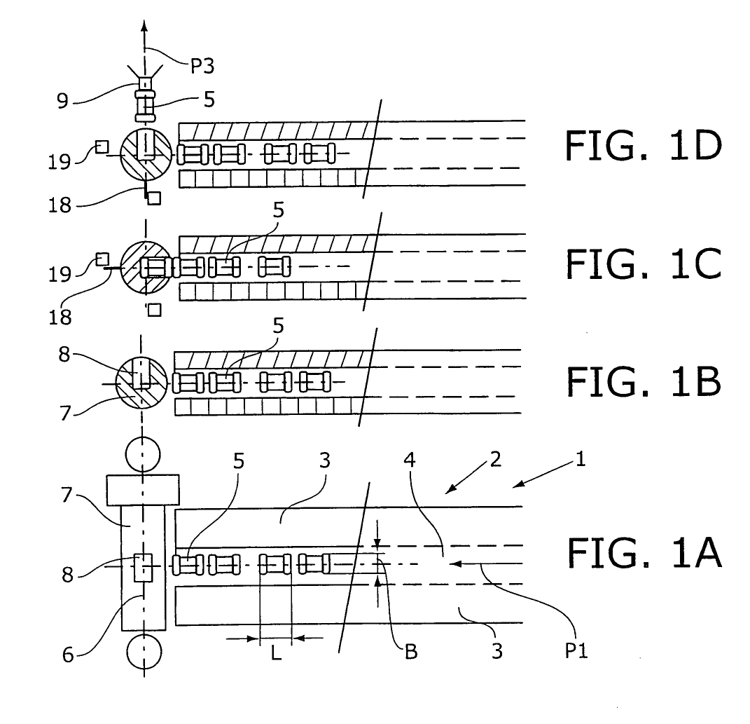

FIGS. 1A-1E schematically show the principle of the method according to the invention;

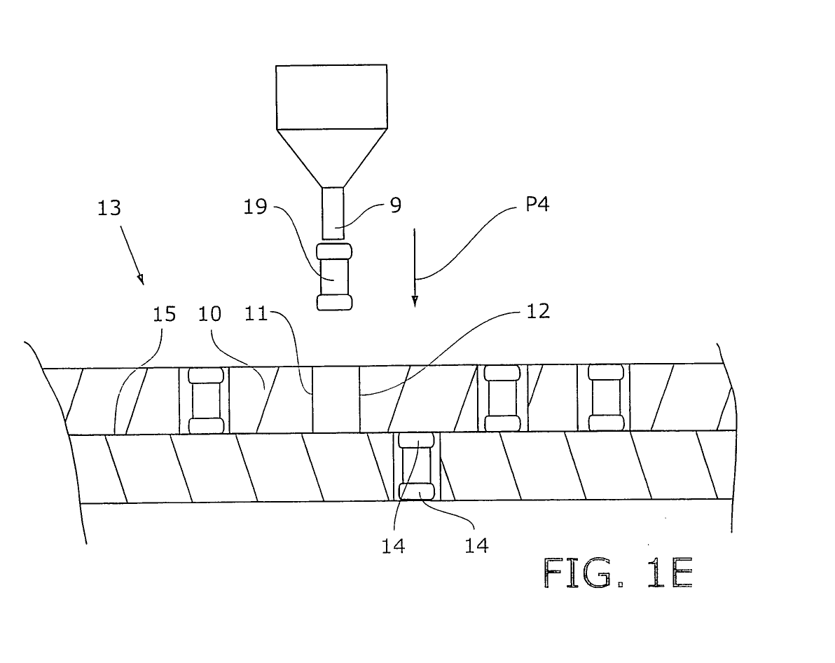

FIGS. 2A and 2B are side views of the device according to the invention while the component is being supplied and pivoted, respectively;

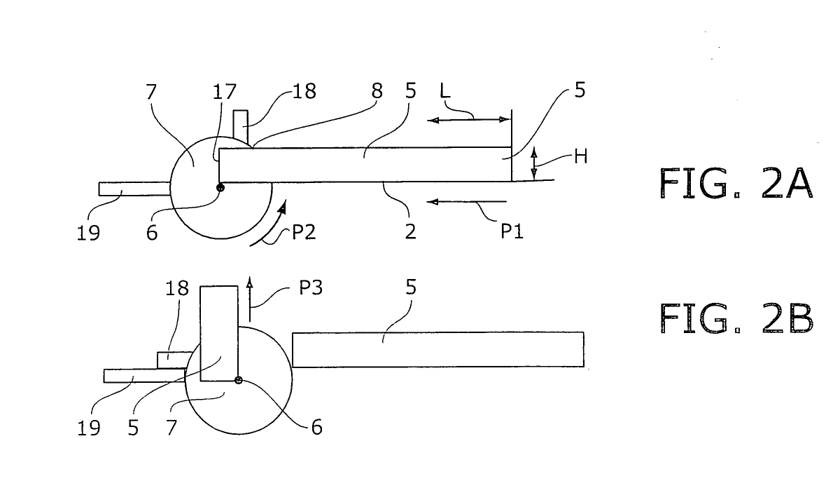

FIG. 3 is a schematic side view of a bulk cassette of the device according to the invention;

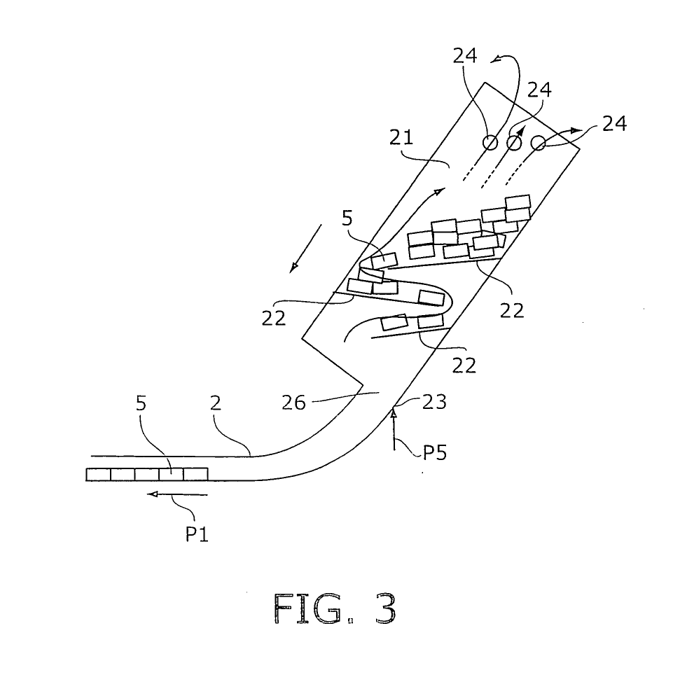

FIG. 4 is a schematic side view of a second embodiment of a device according to the invention;

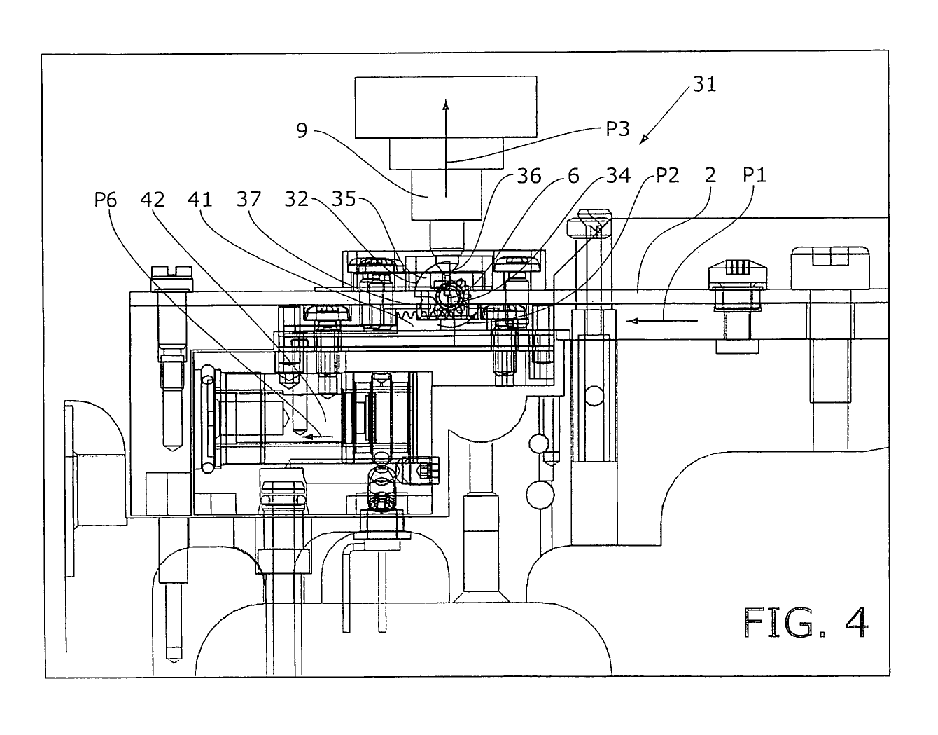

FIG. 5 shows a detail of the device shown in FIG. 4:

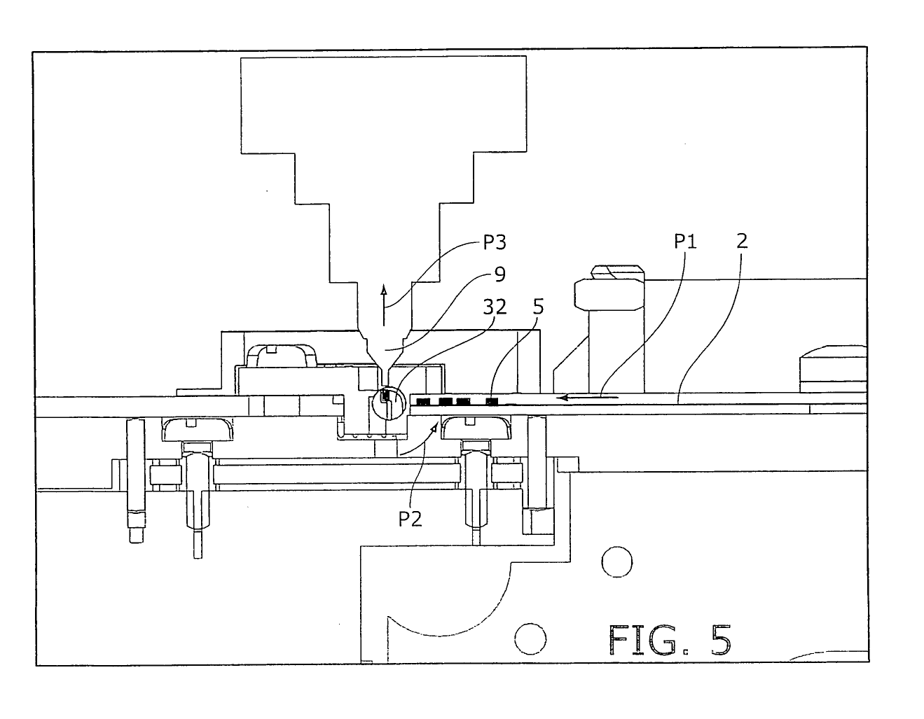

FIG. 6 is a perspective view of a detail of the device shown in FIGS. 4, 5;

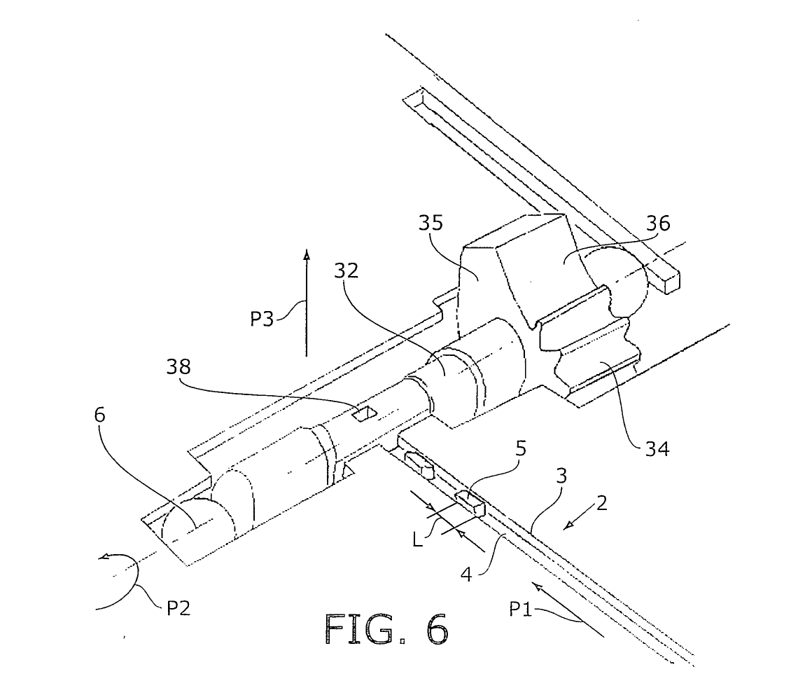

FIGS. 7A, 7B are perspective views of a cylindrical element of the device shown in FIGS. 4-6; and

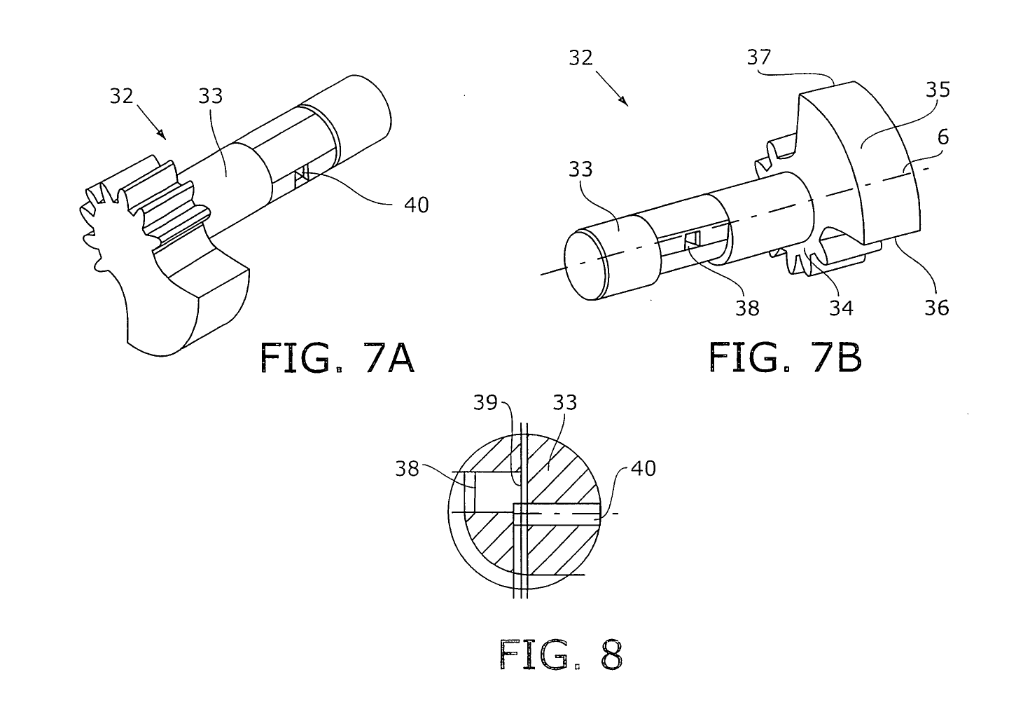

FIG. 8 is a cross-sectional view of the cylindrical element shown in FIGS. 7A-7B.

Like parts are indicated by the same numerals in the figures.

FIG. 1A shows a top plan view of a part of a device 1 according to the invention, which is provided with an elongated guide 2 made up of at least two side walls 3 and a gutter 4 present therebetween. Components 5 are moved from a bulk cassette (see FIG. 3) in the supply direction indicated by the arrow P1. Each component has a length L, a width B and a height H, wherein L>B>H. The component 5 is moved in the supply direction indicated by the arrow P1. with the length L extending parallel to the supply direction, the width B extending transversely to the supply direction and the height H extending transversely to the supply direction and transversely to the gutter 4.

The device 1 is furthermore provided with a cylindrical element 7 which is pivotable about a pivot axis 6, which cylindrical element comprises a chamber 8 which extends transversely to the pivot axis 6. In a first supply position, the chamber 8 extends parallel to the supply direction P1, such that a frontmost component 5 can be moved into the chamber 8 in the supply direction P1 (see FIG. 1B). The cylindrical element 7 is then pivoted in the direction indicated by the arrow P2 about the pivot axis 6 to the pickup position shown in FIG. 1B. Said pivoting causes the component 5 to be pivoted about the pivot axis 6 extending transversely to the longitudinal direction and the vertical direction.

Following that, the component 5 is picked up by means of a pickup element 9 (see FIG. 1D), using a vacuum, for example, and moved in the pickup direction indicated by the arrow P3. The component 5 is then moved in horizontal direction by means of the pickup element 9 to a position 11 on a substrate 10, at which position the substrate 10 may be provided with an opening 12, into which the component 5 is to be positioned. Above the position 11 the element 9 is to that end moved in vertical direction indicated by the arrow P4, opposite to the direction indicated by the arrow P3 until the component 5 is positioned in the opening 12. The longitudinal direction L of the component extends transversely to the substrate 10 in this situation. Such substrates 10 are stacked in a usual manner to form a composite substrate 13 (see FIG. 1E). Contacts 14 of the components 5 make contact with track patterns (not shown) on surfaces 15 of the substrates 10 in this situation.

Using the device 1 according to the invention, components can be supplied from a bulk cassette in a usual manner and then be pivoted about the pivot axis 6 by means of a cylindrical element 7 according to the invention, so that the components 5 can subsequently be positioned in longitudinal direction on the substrate 10.

FIGS. 2A and 2B are further schematic views of the method and device according to the invention, which clearly show that the chamber 8 is provided with a stop 17. The cylindrical element 7 is further provided with a cam 18, which abuts against a first support (not shown) in the supply position of the chamber that is shown in FIG. 2A, and which abuts against a second support 19 after rotation of the cylindrical element 7 in the direction indicated by the arrow P2. Said supports, together with the cam 18, thus limit the angle through which the cylindrical element 7 can be pivoted into the direction indicated by the arrow P2 and in the opposite direction. Here, this angle is 90 degrees.

FIG. 3 shows a bulk cassette 21 of the device 1 according to the invention, which is provided with a number of support walls 22, on which the components 5 are supported. The bulk cassette 21 is further provided with an air inlet 23 and air outlets 24. Air is blown into the bulk cassette 21 in the direction indicated by the arrow P5 via the air inlet 23, causing the components 5 to become detached from each other and to be gradually moved out of the bulk cassette 21 and into the guide 2 via an opening 26 under the influence of the force of gravity. On a side remote from the bulk cassette 21, the guide 2 is provided with the cylindrical element 7 shown in FIGS. 2A and 2B.

FIGS. 4-8 are views of a device 31 according to the invention, which is provided with a bulk cassette 21 (see FIG. 3), a guide 2 joining said bulk cassette, an element 32, which is pivotable about a pivot axis 6, and a pickup element 9, which is movable in a pickup direction indicated by the arrow P3, which pickup direction extends transversely to the pivot axis 6 and the supply direction.

As FIGS. 6, 7A and 7B clearly show, the element 32 is provided with a cylindrical element 33 and with a part of a gear 34 connected to one end of the cylindrical element 33. The element 32 is furthermore provided with a cam 35 connected to the gear 34, which comprises stop surfaces 36, 37 on either side thereof. The cylindrical element 33 is provided with a chamber 38 extending transversely to the pivot axis 6, a bottom of which chamber forms a stop 39. A passage 40 connects to the chamber 38, which passage extends from the chamber 38 to outside the cylindrical element 33.

The gear 34 meshes with a rack 41 extending in the supply direction P1, which rack can be moved in the direction indicated by the arrow P6 and in the opposite direction by means of a pneumatic piston-cylinder combination 42.

The device 31 operates as follows.

The rack 41 is moved in the direction indicated by the arrow P6 by means of the piston-cylinder combination 42, as a result of which the cylindrical element 33 is pivoted in the opposite direction of the arrow P2 about the pivot axis 6 until the stop surface 36 abuts against a support. In this position, the chamber 38 is in line with the guide 2. A component 5 is moved in the supply direction indicated by the arrow P1 until the component 5 is positioned within the chamber 38. Then the rack 41 is moved in the opposite direction of the arrow P6 by means of the piston-cylinder combination 42, as a result of which the cylindrical element 32, and thus the component 5 present therein, is pivoted in the direction indicated by the arrow P2 until the stop surface 39 abuts against a support. In this situation the longitudinal direction L of the component extends vertically, in the direction indicated by the arrow P3. Following that, the component 5 is moved in the direction indicated by the arrow P3 by means of the pickup element 9 and placed on a substrate.

The chamber 38 is preferably so dimensioned that the component is accurately positioned therein. The passage 40 prevents the component 5 being positioned in the chamber in such a manner that a sub-atmospheric pressure would be generated in the chamber 38 upon removal of the component 5 from the chamber 38, as a result of which the component 5 could only be removed from the chamber 38 with relatively much force.

It is also possible to have the guide 2 extend at an angle, in which case the component is pivoted through an angle of less than 90° to a vertical position.

It is also possible to have the element 32 pivot in a different manner about the pivot axis 6.

1. A method for placing a component on a substrate, which component is moved in a supply direction until it abuts against a stop, after which the component is moved at least in a vertically extending pick-up direction and subsequently positioned on the substrate, characterised in that the component is pivoted near said stop, about a pivot axis that extends transversely to the supply direction and the pick-up direction.

2. A method according to claim 1, characterised in that the component is moved with its longitudinal direction in the supply direction, after which it is pivoted about the pivot axis and subsequently moved with its longitudinal direction in the pickup direction.

3. A method according to claim 2, characterised in that the supply direction extends transversely to the pickup direction.

4. A device suitable for placing a component on a substrate, which device is provided with a guide comprising a stop for moving the component in a supply direction, as well as with a pickup element for moving the component in an at least vertically extending pickup direction, characterised in that the device further comprises means located near said stop for pivoting the component about a pivot axis extending transversely to the supply direction and the pickup direction.

5. A device according to claim 4, characterised in that said means comprise a cylindrical element which is pivotable about said pivot axis, which element is provided with a chamber which extends transversely to the pivot axis and which is provided with said stop on a side remote from the guide.

6. A device according to claim 4 or 5, characterised in that the supply direction extends transversely to the pickup direction.
